(19) United States
(12) Patent Application Publication
(10) Pub. No.: US 2016/0064607 A1
(43) Pub. Date: Mar. 3, 2016

(54) NANOSTRUCTURE SEMICONDUCTOR LIGHT EMITTING DEVICE

(71) Applicant: SAMSUNG ELECTRONICS CO., LTD., Suwon-si (KR)

(72) Inventors: Geon Wook YOO, Seongnam-si (KR); Sung Hyun SIM, Uiwang-si (KR); Dong Kuk LEE, Suwon-si (KR); Hye Seok NOH, Suwon-si (KR)

(21) Appl. No.: 14/698,717

(22) Filed: Apr. 28, 2015

(30) Foreign Application Priority Data
Sep. 1, 2014 (KR) 10-2014-0115701

(51) Int. Cl. H01L 33/24; H01L 33/08

(52) U.S. Cl. CPC H01L 33/24; H01L 33/08

(57) ABSTRACT

A nanostructure semiconductor light emitting device may include: a base layer formed of a first conductivity-type semiconductor material; an insulating layer disposed on the base layer and having a plurality of openings exposing portions of the base layer; a plurality of nanocores disposed on the exposed portions of the base layer and formed of a first conductivity-type semiconductor material, each of which including a tip portion having a crystal plane different from that of a side surface thereof; a first high resistance layer disposed on the tip portion of the nanocore and formed of an oxide containing an element which is the same as at least one of elements constituting the nanocore; an active layer disposed on the first high resistance layer and the side surface of the nanocore; and a second conductivity-type semiconductor layer disposed on the active layer.

### CROSS-REFERENCE TO RELATED APPLICATION

This application claims priority to Korean Patent Application No. 10-2014-0115701 filed on Sep. 1, 2014, with the Korean Intellectual Property Office, the disclosure of which is incorporated herein by reference.

### TECHNICAL FIELD

The present disclosure relates to a nanostructure semiconductor light emitting device.

### BACKGROUND

A semiconductor light emitting device such as a light emitting diode (LED) is a device including a material that emits light, in which energy generated through electron-hole recombination is converted into light to be emitted therefrom. LEDs are commonly used as light sources in lighting devices, display devices, and the like, and the development of LEDs has thus been accelerated.

In recent years, semiconductor light emitting devices using nanostructures and technologies for manufacturing the same have been proposed to improve crystallinity and luminous efficiency. In such a semiconductor light emitting device using nanostructures, the generated heat may be relatively reduced and a surface area may be increased due to the use of nanostructures, whereby a light emitting area may be increased to enhance luminous efficiency. In addition, an active layer may be obtained from a non-polar plane or a semi-polar plane, whereby luminous efficiency resulting from polarization may be prevented and efficiency droop characteristics may be improved.

However, the tip portion and side surface of such a nanostructure may have different crystal planes. In this case, even when the entire active layer is grown under the same growth conditions, portions of the active layer disposed on the tip portion and the side surface of the nanostructure may have different compositions and emit light having different wavelengths. In addition, semiconductor layers grown on the tip portion of the nanostructure may be relatively thin as compared to those grown on the side surface thereof, and thus, the possibility of leakage currents may be increased.

### SUMMARY

An exemplary embodiment of the present disclosure may provide a novel nanostructure semiconductor light emitting device resolving a leakage current problem occurring in nanostructures and alleviating problematic wavelength changes of emitted light.

According to an exemplary embodiment of the present disclosure, a nanostructure semiconductor light emitting device may include: a base layer formed of a first conductivity-type semiconductor material; an insulating layer disposed on the base layer and having a plurality of openings exposing portions of the base layer; a plurality of nanocores disposed on the exposed portions of the base layer and formed of the first conductivity-type semiconductor material, each of which including a tip portion having a crystal plane different from that of a side surface thereof; a first high resistance layer disposed on the tip portion of the nanocore and formed of an oxide containing an element which is the same as at least one of elements constituting the nanocore; an active layer disposed on the first high resistance layer and the side surface of the nanocore; and a second conductivity-type semiconductor layer disposed on the active layer.

The nanostructure semiconductor light emitting device may further include a second high resistance layer disposed on a surface of the second conductivity-type semiconductor layer.

The second high resistance layer may be formed of an oxide containing an element which is the same as at least one of elements constituting the second conductivity-type semiconductor layer.

The nanostructure semiconductor light emitting device may further include an ohmic-contact electrode disposed on the second conductivity-type semiconductor layer, wherein at least a portion of the second conductivity-type semiconductor layer may be exposed above the ohmic-contact electrode.

The second high resistance layer may be disposed on the exposed portion of the second conductivity-type semiconductor layer.

The nanocores may be provided in some of the plurality of openings; and portions of the base layer exposed through the other openings may be covered with a third high resistance layer.

The third high resistance layer may be formed of an oxide containing an element which is the same as at least one of elements constituting the first conductivity-type semiconductor material.

The nanostructure semiconductor light emitting device may further include a second electrode covering the third high resistance layer.

The first high resistance layer may include a material having a higher energy bandgap than that of the first conductivity-type semiconductor material forming the nanocore.

The first high resistance layer may be formed of Ga₂O₃ or Ga₃O₃N.

The first high resistance layer may have a thickness of approximately 100 nm or more.

The side surface of the nanocore may have an m-plane, and the tip portion of the nanocore may have an r-plane.

The side surface of the nanocore may have a crystal plane perpendicular to a top surface of the base layer.

According to another exemplary embodiment of the present disclosure, a nanostructure semiconductor light emitting device may include: a base layer formed of a first conductivity-type semiconductor material; a plurality of light emitting nanostructures disposed on the base layer to be spaced apart from each other, each of which including a nanocore formed of the first conductivity-type semiconductor material and an active layer and a second conductivity-type semiconductor layer sequentially disposed on the nanocore; and a high resistance layer disposed on a tip portion of the nanocore and formed of an oxide containing an element which is the same as at least one of elements constituting the second conductivity-type semiconductor layer.

The nanostructure semiconductor light emitting device may further include an ohmic-contact electrode disposed on the plurality of light emitting nanostructures.

According to another exemplary embodiment of the present disclosure, a nanostructure semiconductor light emitting device may include: a base layer formed of a first conductivity-type semiconductor material; an insulating layer disposed on the base layer and having a plurality of openings exposing portions of the base layer; a plurality of light emitting nanostructures formed on the base layer, each light emitting nanostructure including a nanocore formed of the first conductivity-type semiconductor material and an active layer and a second conductivity-type semiconductor layer sequentially disposed on the nanocore; and a plurality of oxide layers containing an element which is the same as at least one of elements constituting one of the nanocore and the second conductivity-type semiconductor layer. Each opening may overlap with at least one of the oxide layers.

A tip portion of one of the plurality of light emitting nanostructures may include one of the plurality of oxide layers.

The one of the plurality of oxide layers may be interposed between the nanocore and the active layer.

The one of the plurality of oxide layers may be directly formed on the second conductivity-type semiconductor layer.

Each nanocore may include a tip portion having a crystal plane different from that of a side surface thereof.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a cross-sectional view of a nanostructure semiconductor light emitting device according to an exemplary embodiment of the present disclosure;

FIGS. 2A and 2B are perspective views illustrating examples of a nanocore used in exemplary embodiments;

FIGS. 3A through 3G are cross-sectional views illustrating a method of manufacturing the nanostructure semiconductor light emitting device according to an exemplary embodiment of the present disclosure;

FIGS. 4A through 4E are cross-sectional views illustrating an example of a high resistance layer formation process applicable to the nanostructure semiconductor light emitting device of FIG. 3G;

FIGS. 5A through 5C are cross-sectional views illustrating an example of an electrode formation process applied to the resultant product illustrated in FIG. 4E;

FIGS. 6 and 7 are views illustrating examples of a backlight including a nanostructure semiconductor light emitting device according to an exemplary embodiment of the present disclosure;

FIG. 8 is a view illustrating an example of a lighting device including a nanostructure semiconductor light emitting device according to an exemplary embodiment of the present disclosure; and

FIG. 9 is a view illustrating an example of a headlamp including a nanostructure semiconductor light emitting device according to an exemplary embodiment of the present disclosure.

### DETAILED DESCRIPTION

Exemplary embodiments in the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

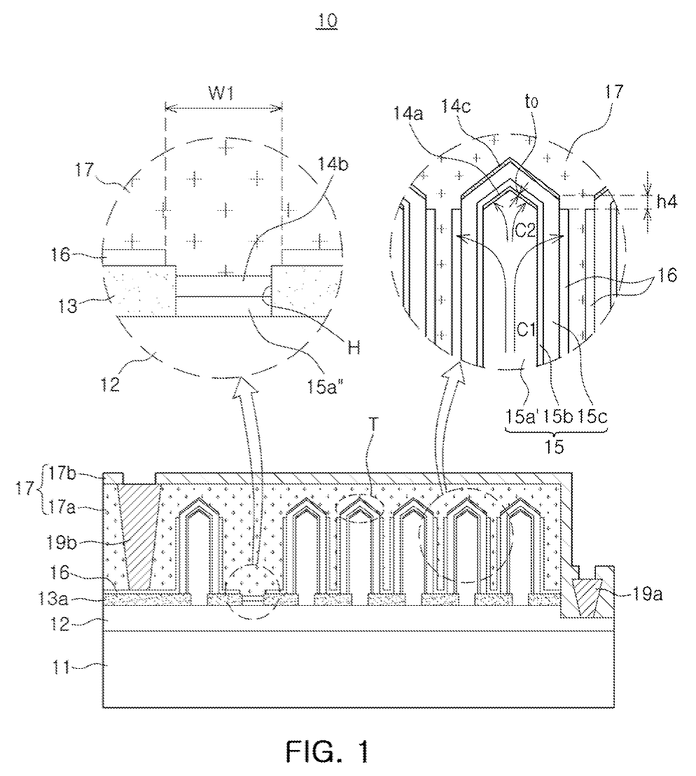

FIG. 1 is a cross-sectional view of a nanostructure semiconductor light emitting device according to an exemplary embodiment of the present disclosure.

As illustrated in FIG. 1, a nanostructure semiconductor light emitting device 10 according to the present exemplary embodiment may include a base layer 12 formed of a first conductivity-type semiconductor material, and a plurality of light emitting nanostructures 15 disposed on the base layer 12.

The base layer 12 may be formed on a substrate 11, and may not only provide a growth surface for the light emitting nanostructures 15 but may also serve to form electrical connections between portions of the light emitting nanostructures 15 having the same polarity.

The substrate 11 may be an insulating substrate, a conductive substrate, or a semiconductor substrate. For example, the substrate 11 may be formed of sapphire, SiC, Si, MgAl₂O₄, MgO, LiAlO₂, LiGaO₂, or GaN. The base layer 12 may be formed of a nitride semiconductor satisfying AlₓIn_{y}Ga_{1-x-y}N (0≦x<1, 0≦y<1, 0≦x+y<1), and may be doped with impurities to have a particular conductivity-type. For example, the base layer 12 may be doped with n-type impurities such as silicon (Si).

An insulating layer 13a having openings may be formed on the base layer 12 and the openings H may be provided to facilitate growth of the light emitting nanostructures 15 (especially, nanocores 15a′). Portions of the base layer 12 may be exposed through the openings H, and the nanocores 15a′ may be formed on the exposed portions of the base layer 12. The insulating layer 13a may be used as a mask for growth of the nanocores 15a′. The insulating layer 13a may be formed of an insulating material such as SiO₂ or SiNₓ that may be used in a semiconductor process.

Each of the light emitting nanostructures 15 may include the nanocore 15a′ formed of a first conductivity-type semiconductor material and an active layer 15b and a second conductivity-type semiconductor layer 15c sequentially formed on a surface of the nanocore 15a′.

The nanocore 15a′ may be formed of a nitride semiconductor satisfying AlₓIn_{y}Ga_{1-x-y}N (0≦x<1, 0≦y<1, 0≦x+y<1), similar to the material of the base layer 12. For example, the nanocore 15a′ may be formed of n-type GaN. The active layer 15b may include a multi-quantum well (MQW) structure in which quantum well layers and quantum barrier layers are alternately stacked. For example, in a case in which the active layer 15b is formed of a nitride semiconductor, a GaN/InGaN structure may be used. However, a single quantum well (SQW) structure may also be used. The second conductivity-type semiconductor layer 15c may be a crystal satisfying p-type AlₓIn_{y}Ga_{1-x-y}N (0≦x<1, 0≦y<1, 0≦x+y<1).

The nanostructure semiconductor light emitting device 10 may include a contact electrode 16 having ohmic contact with the second conductivity-type semiconductor layer 15c. The contact electrode 16 used in the present exemplary embodiment may be formed of a transparent electrode material in order to emit light in a direction opposite to the substrate 11. For example, the contact electrode 16 may include a transparent electrode material such as indium tin oxide (ITO). As necessary, graphene may be used therefor.

The contact electrode 16 may include at least one of silver (Ag), nickel (Ni), aluminum (Al), rhodium (Rh), palladium (Pd), iridium (Ir), ruthenium (Ru), magnesium (Mg), zinc (Zn), platinum (Pt), and gold (Au), but is not limited thereto. The contact electrode 16 may be provided as a single layer or a plurality of layers such as Ni/Ag, Zn/Ag, Ni/Al, Zn/Al, Pd/Ag, Pd/Al, Ir/Ag, Ir/Au, Pt/Ag, Pt/Al, Ni/Ag/Pt and the like. As necessary, the contact electrode 16 may be provided as a reflective electrode structure to form a flip-chip structure.

The contact electrode 16 may only be formed on side surfaces of the light emitting nanostructures 15, while not being formed on tip portions T of the light emitting nanostructures 15. Here, the top of the contact electrode 16 disposed on the side surfaces of the light emitting nanostructures 15 may be spaced apart from the tip portions T of the light emitting nanostructures 15 by a predetermined interval h4, in consideration of manufacturing tolerance.

An insulating protective layer 17 may be formed on the surfaces of the light emitting nanostructures 15. Such an insulating protective layer 17 may protect the light emitting nanostructures 15 as a passivation layer. As in the present exemplary embodiment, even after the contact electrode 16 is formed, a space may be present between the light emitting nanostructures 15, and thus the insulating protective layer 17 may be formed to fill the space. The insulating protective layer 17 may be formed of an insulating material such as SiO₂ or SiNₓ. Specifically, the insulating protective layer 17 may include a material capable of easily filling the space between the light emitting nanostructures 15, such as tetraethyl orthosilicate (TEOS), borophosphosilicate glass (BPSG), CVD-SiO₂, spin-on glass (SOG), and spin-on dielectric (SOD).

The insulating protective layer 17 may be formed to include a first passivation layer 17a and a second passivation layer 17b, as necessary.

The first passivation layer 17a and the second passivation layer 17b may be formed of different materials, or may be provided as separate layers formed of the same material.

Here, the first passivation layer 17a may be disposed to fill the space between the light emitting nanostructures 15, thereby protecting the light emitting nanostructures 15. In addition, the second passivation layer 17b may be disposed to cover and protect the exposed portions of the light emitting nanostructures 15, while firmly supporting first and second electrodes 19a and 19b. The second passivation layer 17b may be formed of a material the same as or similar to that of the first passivation layer 17a.

The present inventive concept is not limited by the filling of the insulating protective layer 17. For example, an electrode component related to the contact electrode 16 may be provided to fill the entirety or a portion of the space between the light emitting nanostructures 15.

The nanostructure semiconductor light emitting device 10 may include the first electrode 19a and the second electrode 19b. The first electrode 19a may be disposed on the exposed portion of the base layer 12 formed of the first conductivity-type semiconductor material. In addition, the second electrode 19b may be disposed on an extended and exposed portion of the contact electrode 16.

As illustrated in FIG. 1, the nanocore 15a′ may include the tip portion T having a crystal plane different from that provided on the side surfaces of the nanocore 15a′. As illustrated in FIG. 1, the tip portion of the nanocore 15a′ may have an inclined crystal plane different from that provided on the side surfaces of the nanocore 15a′. For example, the tip portion of the nanocore 15a′ may have a hexagonal pyramid shape.

A first high resistance layer 14a may be formed on the surface of the tip portion of the nanocore 15a′. The first high resistance layer 14a may be disposed between the active layer 15b and the nanocore 15a′.

The first high resistance layer 14a may be formed of a material having high electrical resistance so as to prevent leakage currents that may be generated in the tip portion of the nanocore 15a′. The first high resistance layer 14a may be formed of an oxide including the same element as that of the nanocore 15a′. For example, the first high resistance layer 14a may be formed of a material such as Ga₂O₂ or Ga₃O₃N obtained by oxidizing the tip portion of the nanocore 15a′.

The first high resistance layer 14a may be formed by oxidizing the nanocore 15a′. For example, the first high resistance layer 14a may be formed through oxygen (O₂) plasma treatment, implantation of hydrogen ions (H⁺) or oxygen ions (O²⁻), or oxidizing treatment using an etchant such as H₂O₂. The first high resistance layer 14a may have a thickness t₀ of approximately 100 nm or more so as to have sufficient electrical resistance.

The first high resistance layer 14a used in the present exemplary embodiment may only be disposed on the tip portion of the nanocore 15a′. Such a selective disposition of the first high resistance layer 14a may prevent a portion of the active layer disposed above the tip portion of the nanocore 15a′ from emitting light. That is, a current flow C1 through a portion of the active layer disposed on the side surfaces of the nanocore 15a′ may be normal, while a current flow C2 through a portion of the active layer disposed above the tip portion of the nanocore 15a′ may be blocked by the first high resistance layer 14a. Alternatively, a second high resistance layer 14c may be formed on a portion of the second conductivity-type semiconductor layer 15c disposed above the tip portion of the nanocore 15a′, instead of forming the first high resistance layer 14a on the tip portion of the nanocore 15a′. That is, the first and second high resistance layers 14a and 14c may be selectively formed.

As described above, only the portion of the active layer formed on the same crystal plane (the side surfaces of the nanocore) may contribute to the emission of light. Even in the case that the other portion of the active layer formed on the different crystal plane (the tip portion of the nanocore) has different compositions, an effect arising therefrom on wavelengths of emitted light (e.g., an increase in full width at half maximum (FWHM)) may be minimized. As a result, light having a desired wavelength may be produced with precision.

In addition, such a high resistance layer may be formed in a region W1 in which the light emitting nanostructure 15 is broken. In general, a light emitting nanostructure has a high aspect ratio, and thus, may be vulnerable to impacts during the manufacturing process. Therefore, in a case in which the light emitting nanostructure 15 is broken during the manufacturing process, the nanocore 15a′ or the base layer 12 may be exposed. Since the nanocore 15a′ and the base layer 12 are formed of the first conductivity-type semiconductor material, in a case in which the electrode (especially, the second electrode) is formed thereon, a leakage current may be generated due to low resistance. According to the present exemplary embodiment, a third high resistance layer 14b may be formed in the region W1 in which the light emitting nanostructure 15 is broken, thereby fundamentally blocking the leakage current. Therefore, even in a case in which the second electrode is formed in the region W1 in which the light emitting nanostructure 15 is broken, the leakage current may be prevented. As shown in FIG. 1, if the light emitting nanostructure 15 is formed at the region where the opening H is formed, in a direction perpendicular to a surface of the substrate 11 on which the plurality of light emitting nanostructures 15 are formed, the opening H may be overlapped with the first and second high resistance layers 14a and 14c. On the other side, if the light emitting nanostructure 15 is not formed at the region where the opening H is formed due to a broken structure, in the direction perpendicular to the surface of the substrate 11, the opening H may be overlapped with the third high resistance layer 14b.

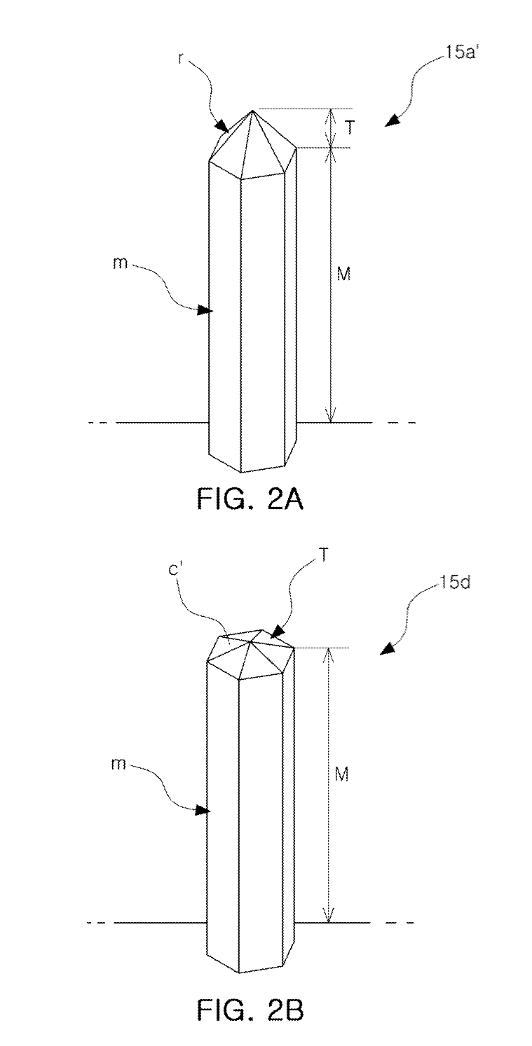

Effects arising from crystal planes of a nanocore that may be used in exemplary embodiments will be detailed with reference to FIGS. 2A and 2B.

The nanocore 15a′ illustrated in FIG. 2A may be divided into a main portion M providing side surfaces, each of which is a first crystal plane, and a tip portion T providing surfaces, each of which is a second crystal plane different from the first crystal plane, in a growth direction.

In a case in which the nanocore 15a′ has a hexagonal crystal structure such as a nitride single crystal, the first crystal plane may be a non-polar plane (e.g. an m-plane) and the second crystal plane may be a semi-polar plane (e.g. an r-plane). The nanocore 15a′ may have a rod structure of which the tip portion T is of a hexagonal pyramid shape.

Even in a case in which the active layer is grown on the surface of the nanocore 15a′ using the same process, the compositions of portions of the active layer (for example, the content of indium (In) in a case of growth of an InGaN layer) may differ due to differences in characteristics of respective crystal planes, and a wavelength of light generated in the active layer grown on the r-plane of the tip portion T of the nanocore 15a′ may be different from a wavelength of light generated in the active layer grown on the m-plane of the side surface of the nanocore 15a′. This may result in an increased FWHM for the wavelength of emitted light and difficulties in producing light having a desired wavelength. In addition, the semiconductor layers (the active layer and the second conductivity-type semiconductor layer) may be relatively thin when grown on the semi-polar plane of the tip portion of the nanostructure, and thus, the leakage current may be concentrated thereon.

In order to solve the aforementioned problems, as illustrated in FIG. 1, the first high resistance layer 14a may be formed on the tip portion of the nanocore 15a′ to lower the leakage current, thereby improving luminous efficiency, and may prevent the portion of the active layer disposed on the tip portion from contributing to the emission of light, thereby producing light having a desired wavelength with precision. The second high resistance layer 14c may be formed on the portion of the second conductivity-type semiconductor layer 15c disposed above the tip portion of the nanocore 15a′, as well as the first high resistance layer formed on the tip portion of the nanocore 15a′, thereby ensuring the blocking of the leakage current. In addition, the third high resistance layer 14b may be formed in the region W1 in which the light emitting nanostructure 15 is broken, thereby fundamentally blocking the leakage current.

Such high resistance layers have high electrical resistance. In a case in which the high resistance layer was formed by performing O₂ plasma treatment on the surface of p-GaN for three minutes as compared with a case in which the corresponding layer was formed without the O₂ plasma treatment, contact resistivity to metals was increased from 6.27 Ω·cm² to 2320 Ω·cm² by approximately 400 times. In this case, the leakage current was reduced from 1 mA to 0.27 mA, approximately ⅓ as compared with the existing case. In addition, the dispersion of FWHM for the wavelength of emitted light was reduced from 60 nm to 35 nm by approximately 40%.

The first high resistance layer 14a may be usefully applied to nanocores of various shapes having different crystal planes, as well as the nanocore illustrated in FIG. 2A, so long as portions of a corresponding nanocore have different crystal planes. For example, as illustrated in FIG. 2B, the first high resistance layer 14a may be similarly applied to a nanocore 15d of which a tip portion T does not have a semi-polar plane.

As illustrated in FIG. 2B, the nanocore 15d, similarly to the nanocore illustrated in FIG. 2A, may have a main portion M providing side surfaces, each of which is a first crystal plane m. The nanocore 15d may have a tip portion T providing surfaces, each of which is a second crystal plane c′ different from the first crystal plane m, but the second crystal plane c′ may not be completely semi-polar.

In the aforementioned structure of the nanocore 15d, the compositions or thicknesses of portions of an active layer grown thereon may differ due to differences in characteristics of respective crystal planes, which may cause a leakage current and differences in wavelengths of light emitted therefrom. By applying the first high resistance layer 14a to the tip portion T of the nanocore 15d prior to forming the active layer, a current may be prevented from flowing to the active layer on the tip portion T of the nanocore 15d. As a result, problems resulting from the leakage current and the differences in the wavelengths of light may be resolved, whereby a high efficient nanostructure semiconductor light emitting device may be provided.

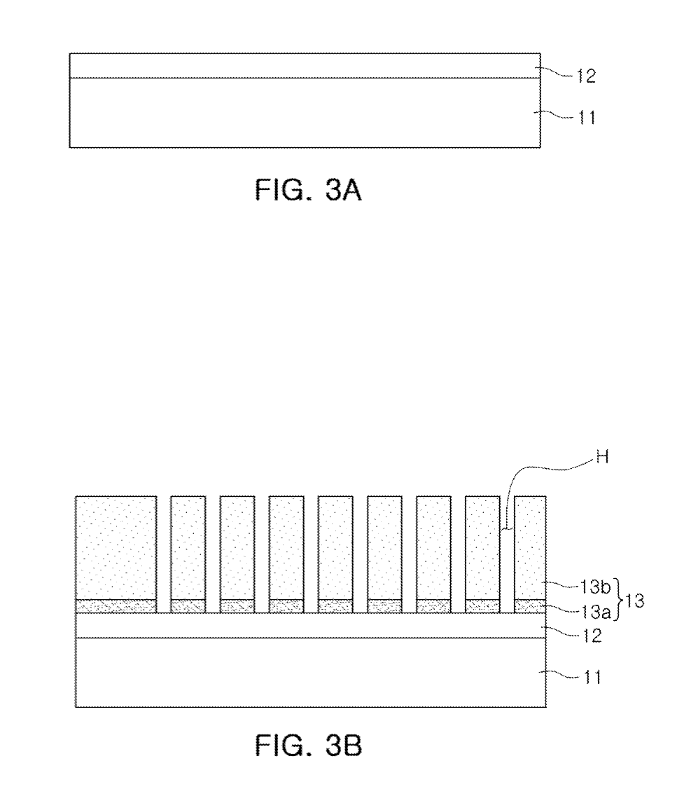

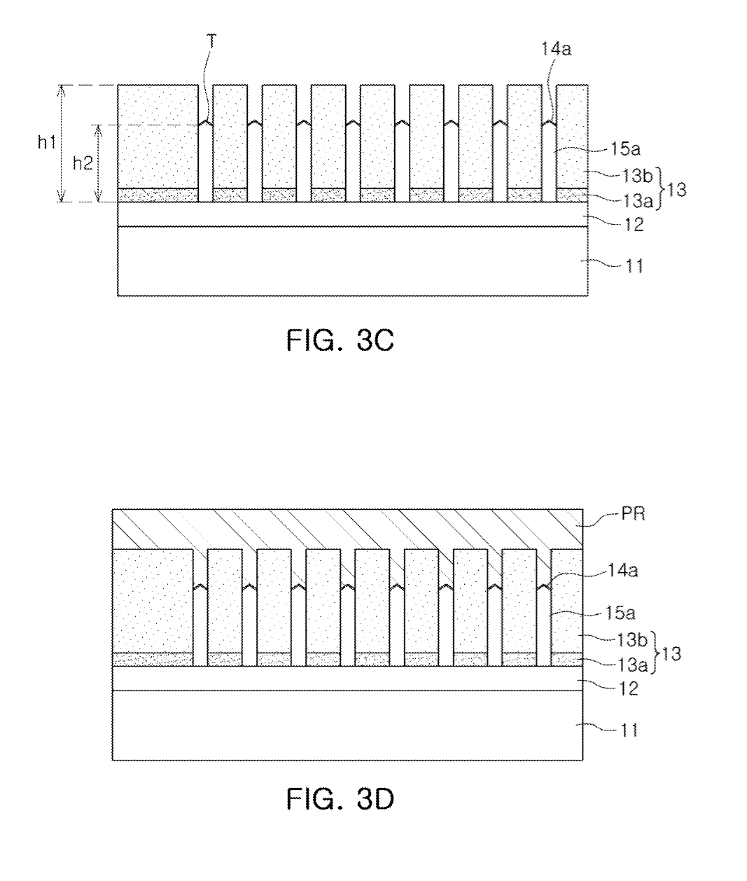

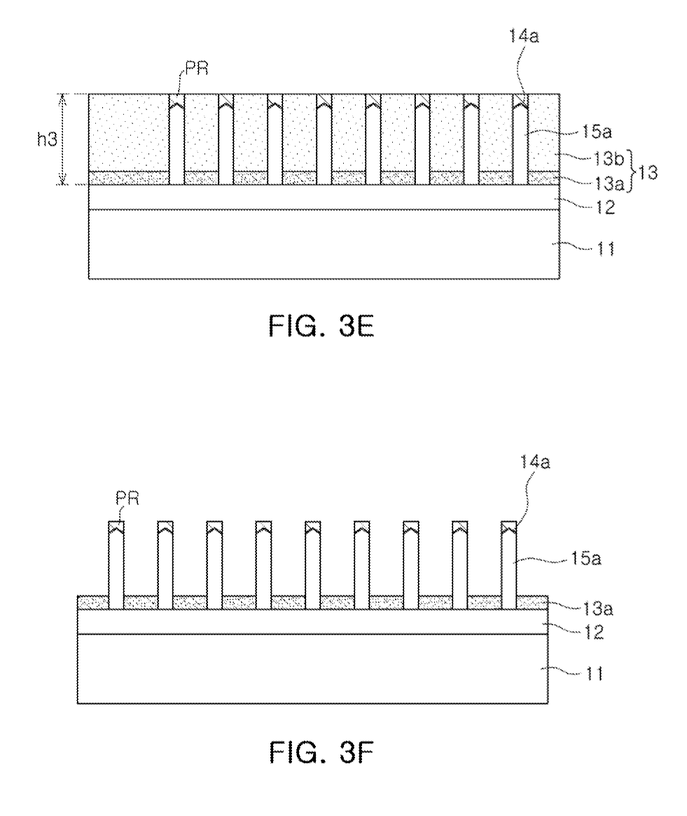

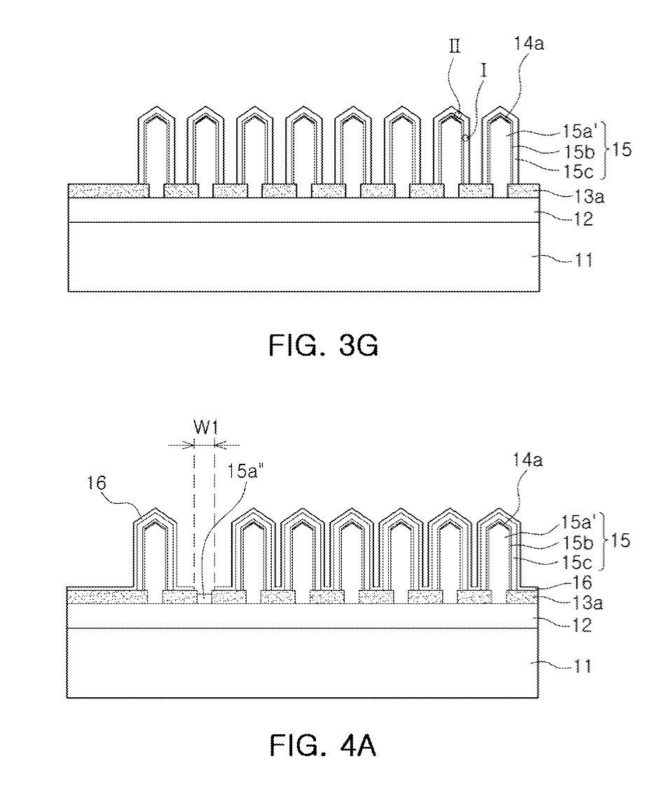

The nanostructure semiconductor light emitting device according to the present exemplary embodiment may be obtained by using various manufacturing methods. FIGS. 3A to 3G are cross-sectional views illustrating a method of manufacturing a nanostructure semiconductor light emitting device according to an exemplary embodiment of the present disclosure, in which a mask is used as a mold and nanocores are grown by filling spaces in the mask.

As illustrated in FIG. 3A, a first conductivity-type semiconductor material may be grown on the substrate 11 to form a base layer 12.

The base layer 12 may not only provide a crystal growth surface for light emitting nanostructures, but may also be provided as a structure for electrical connections between portions of the light emitting nanostructures having the same polarity. Thus, the base layer 12 may be formed as a semiconductor single crystal having electrical conductivity. In a case in which the base layer 12 is directly grown on the substrate 11, the substrate 11 may be a crystal growth substrate.

Next, as illustrated in FIG. 3B, a mask 13 having a plurality of openings H and an etch stop layer may be formed on the base layer 12.

The mask used in the present exemplary embodiment may include a first material layer 13a formed on the base layer 12, and a second material layer 13b formed on the first material layer 13a and having a higher etching rate than the first material layer 13a.

The first material layer 13a may be provided as the etch stop layer. That is, the etching rate of the first material layer 13a may be lower than the etching rate of the second material layer 13b under the same etching conditions. At least the first material layer 13a may be formed of a material having electrical insulating properties, and the second material layer 13b may also be formed of an insulating material as necessary.

The first and second material layers 13a and 13b may be formed of different materials to obtain a difference in etching rates. For example, the first material layer 13a may be a SiN layer and the second material layer 13b may be a SiO₂ layer. Alternatively, such a difference in etching rates may be obtained using pore density. In this case, the first and second material layers 13a and 13b may be formed of the same insulating material having different porosities.

The overall thickness of the first and second material layers 13a and 13b may be selected in consideration of a desired height of a nanostructure. An etch stop level through the first material layer 13a may be set in consideration of the overall height of the mask 13 from the surface of the base layer 12. After the first and second material layers 13a and 13b are sequentially formed on the base layer 12, the plurality of openings H may be formed to expose portions of the base layer 12. The size of each opening H may be set in consideration of a desired size of the light emitting nanostructure. For example, the width of the opening H may be equal to or less than 500 nm, and further may be equal to or less than 200 nm.

The openings H may be manufactured by using a semiconductor process. For example, the openings may be formed to have a high aspect ratio using a deep-etching process. The aspect ratio of the opening may be equal to or greater than 5:1, and further equal to or greater than 10:1.

When viewed from above, the shapes and arrangements of the openings H may be varied. For example, the shapes of the openings may be polygonal, quadrangular, elliptical, or circular. The opening H is illustrated in FIG. 3B as a rod structure by way of example, but is not limited thereto. The openings H may have various structures using an appropriate etching process. For example, each opening in the mask 13 may have a structure of which a cross-sectional area is gradually reduced in an upward direction thereof.

Next, as illustrated in FIG. 3C, a first conductivity-type semiconductor material may be grown on the exposed portions of the base layer 12 while filling the plurality of openings H, thereby forming the plurality of nanocores 15a. A height h2 of each nanocore 15a′ may be set to not exceed a height h1 of each opening H. In consideration of a subsequent process, the height h2 of the nanocore 15a′ may be set to be equal to or lower than 90% of the height h1 of the opening H.

The first conductivity-type semiconductor material forming the nanocores 15a′ may be an n-type nitride semiconductor material, and may be the same as the first conductivity-type semiconductor material forming the base layer 12. For example, the base layer 12 and the nanocore 15a′ may be formed of n-type GaN.

A nitride single crystal forming the nanocores 15a′ may be formed using metal organic chemical vapor deposition (MOCVD) or molecular beam epitaxy (MBE), and the mask 13 may serve as a mold for the nitride single crystal to be grown and provide the nanocores 15a′ corresponding to the shapes of the openings H. That is, the nitride single crystal may selectively be grown on the portions of the base layer 12 exposed through the openings H of the mask 13, while filling the openings H. Therefore, the shape of the filled nitride single crystal may correspond to the shape of the opening.

Then, with the mask 13 retained in place, the first high resistance layer 14a may be formed on the tip portion T of the nanocore 15a′. The first high resistance layer 14a may be formed by oxidizing the tip portion T of the nanocore 15a′ through O₂ plasma treatment, implantation of hydrogen ions or oxygen ions, or oxidizing treatment using an etchant such as H₂O₂.

Therefore, the first high resistance layer 14a may be easily formed on the tip portion T of the nanocore 15a′ without forming a separate mask.

As described above, the manufacturing process in the present exemplary embodiment may be simplified through the molding process.

Next, as illustrated in FIG. 3D, the surface of the mask 13 may be coated with a photoresist PR to cover the first high resistance layer 14a, and the surface of the photoresist PR may be planarized. Such a planarization may be to provide a uniform top surface when the top portion of the mask 13 is removed in a subsequent process.

Then, as illustrated in FIG. 3E, the mask 13 and the photoresist PR may be dry-etched and removed to a level (height h3) at which the first high resistance layer 14a remains unexposed. The height h3 may be set as a minimum height sufficient to allow the first high resistance layer 14a to remain unexposed. This etching process may be performed by dry-etching such as CF₄ plasma etching.

Subsequently, as illustrated in FIG. 3F, a portion of the mask 13 may be removed before the first material layer 13a serving as the etch stop layer so as to expose side surfaces of the plurality of nanocores 15a.

The removal of the mask 13 may be performed through a chemical etching process. Specifically, the second material layer 13b may be removed by performing a wet-etching process using a buffered oxide etchant (BOE). During this etching process, the mask 13 may be removed, but the photoresist PR remained on the nanocore 15a′ may not be etched. Therefore, the first high resistance layer 14a formed on the tip portion T of the nanocore 15a′ may be retained.

In the present exemplary embodiment, by using the etching process appropriate for selectively removing the second material layer 13b, only the second material layer 13b may be removed, while the first material layer 13a may be retained. The retained first material layer 13a may prevent the active layer 15b and the second conductivity-type semiconductor layer 15c to be grown in a subsequent growth process from contacting the base layer 12.

Then, the photoresist PR retained on the first high resistance layer 14a may be etched and removed. After this process, the nanocores 15a, each of which having the first high resistance layer 14a formed on the tip portion thereof, may be prepared.

In the process of manufacturing the light emitting nanostructures by using the mask having the openings as a mold as in the present exemplary embodiment, an additional heat treatment may be performed in order to improve crystallinity.

After the second material layer 13b is removed from the mask, the surface of the nanocore 15a′ may be heat-treated under predetermined conditions to change the crystal plane of the nanocore 15a′ into a stable plane advantageous for crystal growth, like a semi-polar or non-polar crystal plane.

The nanocore 15a′ may have a crystal plane determined depending on the shape of the opening H. Although differing depending on the shape of the opening, the surface of the nanocore obtained thusly may have a relatively unstable crystal plane, which may not be advantageous for subsequent crystal growth.

As in the present exemplary embodiment, when the opening has a cylindrical rod shape, the nanocore 15a′ may have a curved side surface, rather than a particular crystal plane. When the nanocore 15a′ is heat-treated, unstable crystals on the surface thereof may be rearranged to have a stable crystal plane such as a semi-polar or non-polar plane. As for heat treatment conditions, the nanocore may be heat-treated at a temperature equal to or higher than 800° C., for a few to tens of minutes to obtain a desired stable crystal plane.

For example, when the nanocore 15a′ is grown on a C (0001) plane of a sapphire substrate, the nanocore 15a′ may be heat-treated at 800° C. or higher to thereby convert the curved surface or unstable crystal plane thereof into a non-polar plane (an m-plane). Stabilization of the crystal plane may be achieved through the high temperature heat treatment. It may be understood that in a case in which crystals positioned on the surface of the nanocore are rearranged at a high temperature or a source gas remains within a chamber, such a residual source gas is deposited and partial regrowth for obtaining a stable crystal plane is performed.

In particular, in view of regrowth, a heat treatment process may be performed within a chamber in which a residual source gas is present, or may be performed while a small amount of source gas is supplied on purpose. After the removal of the mask, the heat treatment process may be performed in an MOCVD chamber under conditions similar to those of the nanocore growth process, and may enhance the quality of the surface of the nanocore. That is, through the heat treatment process, non-uniformities (for example, defects, or the like) present on the surface of the nanocore after the removal of the mask may be removed and structural stability (e.g., hexagonal rods) may be greatly enhanced through rearrangement. The heat treatment process may be performed at a temperature similar to the growth temperature of the nanocore, for example, between 800° C. to 1200° C. Due to the aforementioned regrowth, the size of the heat-treated nanocore may be slightly increased.

Subsequently, as illustrated in FIG. 3G, the active layer 15b and the second conductivity-type semiconductor layer 15c may be sequentially grown on the surface of each of the plurality of nanocores 15a′.

Through this process, each of the light emitting nanostructures 15 may have a core-shell structure including the nanocore 15a′ formed of the first conductivity-type semiconductor material, and a shell layer including the active layer 15b enclosing the nanocore 15a′ and the second conductivity-type semiconductor layer 15c.

The tip portion and the side surfaces of the nanocore 15a′ may have different crystal planes. As described above, portions II of the active layer and the second conductivity-type semiconductor layer disposed above the tip portion of the nanocore and portions I of the active layer and the second conductivity-type semiconductor layer disposed on the side surfaces of the nanocore may have different compositions and/or thicknesses. In order to solve the leakage current and the wavelength difference problem arising therefrom, the first high resistance layer 14a may be disposed on the tip portion of the nanocore 15a′. Due to the selective disposition of the first high resistance layer 14a, a current flow through the portion of the active layer disposed on the side surfaces of the nanocore 15a′ may be normal, while a current flow through the portion of the active layer disposed above the tip portion of the nanocore 15a′ may be blocked by the first high resistance layer 14a.

Thus, by preventing the leakage current from being concentrated on the tip portions of the nanocores 15a′, luminous efficiency of the light emitting nanostructures 15 may be improved, and light having a desired wavelength may be produced with precision.

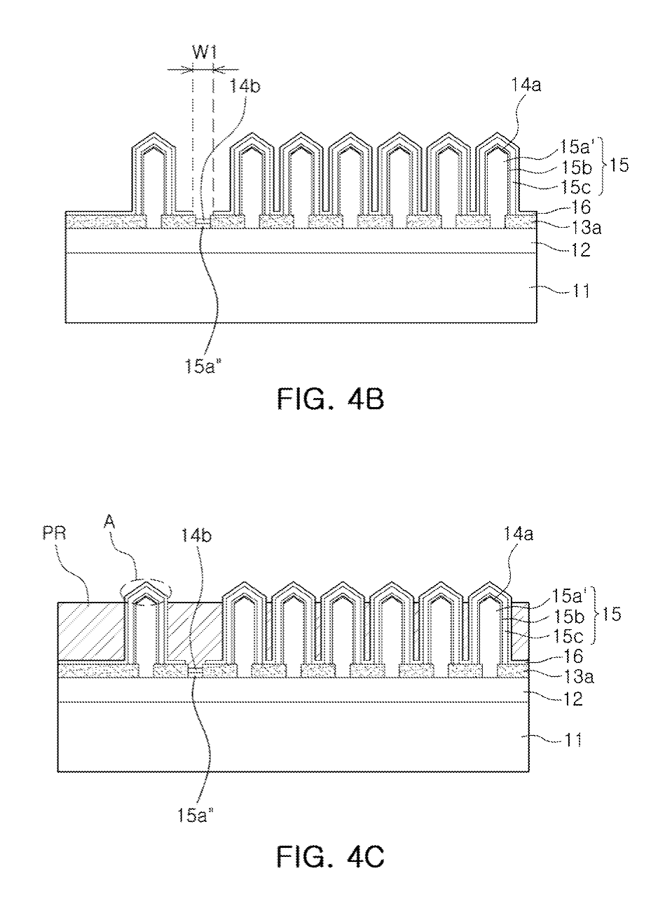

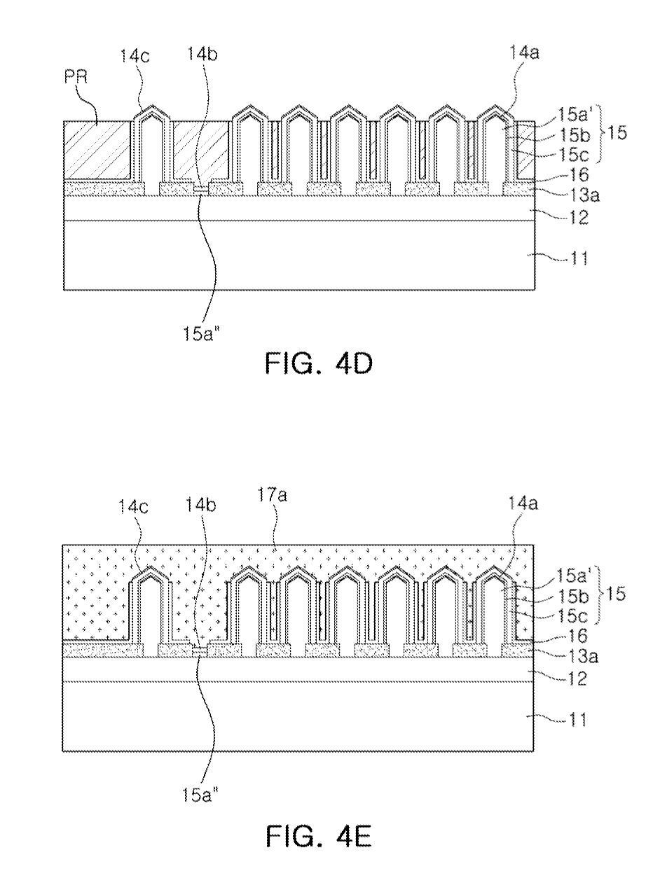

The nanostructure semiconductor light emitting device illustrated in FIG. 3G may further include a high resistance layer having various structures. FIGS. 4A through 4E are cross-sectional views illustrating an example of a high resistance layer formation process applicable to the nanostructure semiconductor light emitting device of FIG. 3G.

As illustrated in FIG. 4A, the contact electrode 16 may be formed on the light emitting nanostructures 15 of FIG. 3G.

The contact electrode 16 may include an ohmic-contact material appropriate for forming ohmic-contact with the second conductivity-type semiconductor layers 15c. As the ohmic-contact material, GaN, InGaN, ZnO or graphene may be used. For example, the contact electrode 16 may include at least one of Ag, Ni, Al, Rh, Pd, Ir, Ru, Mg, Zn, Pt, and Au, and may be provided as a single layer or a plurality of layers such as Ni/Ag, Zn/Ag, Ni/Al, Zn/Al, Pd/Ag, Pd/Al, Ir/Ag, Ir/Au, Pt/Ag, Pt/Al, or Ni/Ag/Pt. In exemplary embodiments, the contact electrode 16 may be formed by using the ohmic-contact material as a seed layer and performing electroplating thereon. For example, after a Ag/Ni/Cr layer is formed as a seed layer, electroplating of Cu/Ni may be performed thereon to form the contact electrode 16.

The contact electrode 16 used in the present exemplary embodiment may employ a reflective metal layer and allow light to be extracted in a direction toward the substrate 11, but is not limited thereto. Alternatively, the contact electrode 16 may include a transparent electrode material such as ITO to allow light to be extracted in a direction toward the light emitting nanostructures 15.

Region W1 refers to a region in which the light emitting nanostructure 15 is broken during the manufacturing process. Since the light emitting nanostructure 15 is formed to have a high aspect ratio, the light emitting nanostructure 15 may be vulnerable to impacts occurring during the manufacturing process. Therefore, in a case in which the light emitting nanostructure 15 is broken during the manufacturing process, the nanocore 15a′ or the base layer 12 may be exposed. Since the nanocore 15a′ and the base layer 12 are formed of the first conductivity-type semiconductor material, in a case in which the electrode is formed thereon, a leakage current may be generated due to low resistance. According to the present exemplary embodiment, in order to block the leakage current, a high resistance layer may be formed in the region W1 in which the light emitting nanostructure 15 is broken, thereby fundamentally blocking the leakage current. In the present exemplary embodiment, a case in which a residue 15a″ of the nanocore 15a′ resulting from the breakage of the corresponding light emitting nanostructure 15 is exposed will be described by way of example.

Next, as illustrated in FIG. 4B, the third high resistance layer 14b may be formed on the residue 15a″ of the nanocore 15a′ exposed in the region W1. In a case in which the surface of the light emitting nanostructures 15 is oxidized, a region in which the contact electrode 16 is formed is not oxidized. Thus, an oxide film may be selectively formed on the surface of the residue 15a″ of the nanocore 15a′ exposed in the region W1. Therefore, the third high resistance layer 14b may only be formed on the region W1 in which the light emitting nanostructure 15 is broken. Such an oxidizing process may be performed through O₂ plasma treatment, implantation of hydrogen ions or oxygen ions, or oxidizing treatment using an etchant such as H₂O₂.

Next, a photoresist PR may be applied to the light emitting nanostructures 15, and then may be etched until the top portion A of the contact electrode 16 is exposed as illustrated in FIG. 4C. Such an etching process may be performed through dry-etching such as CF₄ plasma treatment.

Then, as illustrated in FIG. 4D, the top portion A of the contact electrode 16 may be removed. In a case in which the contact electrode 16 is formed of ITO, the contact electrode 16 may be selectively removed by using an ITO-etchant such as LCE-12K. Through the selective etching process, a portion of the contact electrode 16 disposed on the tip portions of the light emitting nanostructures 15 may be removed to expose the tip portions of the light emitting nanostructures 15. Therefore, the contact electrode 16 may only be disposed on the side surfaces of the light emitting nanostructures 15. In the case in which the portion of the contact electrode is removed, the second conductivity-type semiconductor layer 15c may be exposed to increase contact resistance, whereby a current flow may be restricted. Therefore, the concentration of the leakage current on the tip portions of the light emitting nanostructures 15 may be prevented.

Thereafter, the exposed surface of the second conductivity-type semiconductor layer 15c may be oxidized to form the second high resistance layer 14c. Such an oxidizing process may be performed through O₂ plasma treatment, implantation of hydrogen ions or oxygen ions, or oxidizing treatment using an etchant such as H₂O₂. A portion of the second conductivity-type semiconductor layer 15c other than the exposed surface thereof may be masked by the photoresist PR to not be oxidized, and thus only the top portion of the second conductivity-type semiconductor layer 15c may be oxidized to form the second high resistance layer 14c. The formation of the second high resistance layer 14c may be omitted in a case in which the first high resistance layer 14a is formed.

Then, as illustrated in FIG. 4E, the first passivation layer 17a may be formed to cover the tip portions of the light emitting nanostructures 15. The first passivation layer 17a may be formed using various electrical insulating materials. An insulating protective layer including a material such as SiO₂ or SiNₓ may be used as the first passivation layer 17a. Specifically, in order to easily fill the space between the light emitting nanostructures 15, tetraethyl orthosilicate (TEOS), borophosphosilicate glass (BPSG), CVD-SiO₂, spin-on glass (SOG), or spin-on dielectric (SOD) may be used for the first passivation layer 17a.

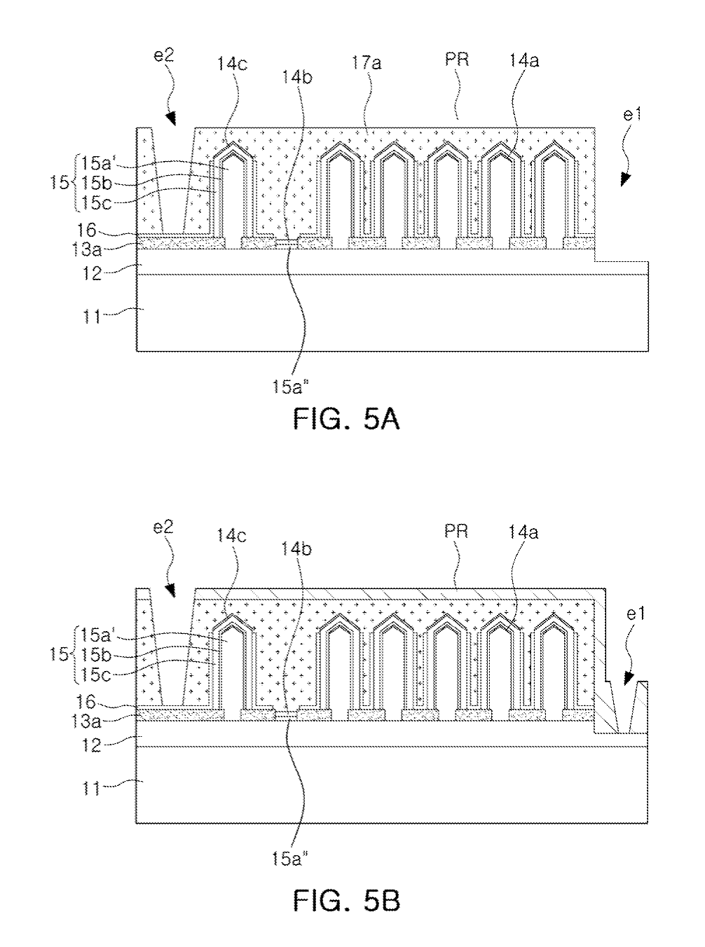

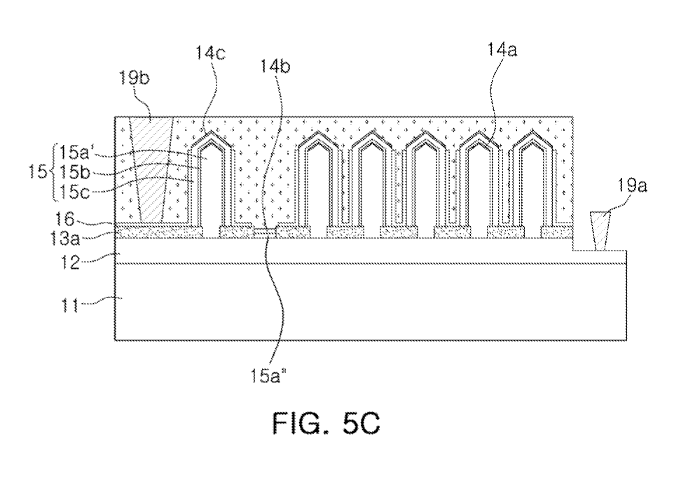

The nanostructure semiconductor light emitting device of FIG. 4E may have various electrode structures. FIGS. 5A through 5C are cross-sectional views illustrating an example of an electrode formation process applicable to the resultant product illustrated in FIG. 4E.

As illustrated in FIG. 5A, the first passivation layer 17a may be selectively removed to expose portions of the base layer 12 and the contact electrode 16, thereby providing a region e1 in which the first electrode is to be formed. In addition, a region e2 in which the second electrode is to be formed may be provided. The first passivation layer 17a may be selectively etched using dry-etching or wet-etching. For example, in a case in which the first passivation layer 17a is formed of an oxide film or a similar material, CF₄ plasma may be used in the dry etching, and an HF-containing etchant such as BOE may be used in the wet etching.

Next, as illustrated in FIG. 5A, the region e1 on which the first electrode is to be formed may be defined. Here, the region e1 on which the first electrode is to be formed may expose a portion of the base layer 12.

The exposed region e1 may be used for the disposition of the first electrode. The removing process may be performed using a photolithography process. In this process, some light emitting nanostructures 15 disposed on the exposed region e1 may be removed; however, by not growing any nanocores on the region on which the electrode is to be formed, the removal of the corresponding light emitting nanostructures 15 may be unnecessary.

Then, as illustrated in FIG. 5B, a photoresist PR may be formed to define the regions e1 and e2 for the first and second electrodes. As illustrated in FIG. 5C, the first electrode 19a and the second electrode 19b may be formed on the regions e1 and e2, respectively. In this process, a common electrode material may be used for the first and second electrodes 19a and 19b. For example, the material for the first and second electrodes 19a and 19b may include Au, Ag, Al, Ti, W, Cu, Sn, Ni, Pt, Cr, TiW, AuSn, or eutectic metals thereof.

Then, as illustrated in FIG. 1, the second passivation layer 17b may be additionally formed as necessary. The second passivation layer 17b along with the first passivation layer 17a may provide the insulating protective layer 17. The second passivation layer 17b may cover and protect the exposed semiconductor portions, while firmly supporting the first and second electrodes 19a and 19b.

The second passivation layer 17b may be formed of a material the same as or similar to the material for the first passivation layer 17a.

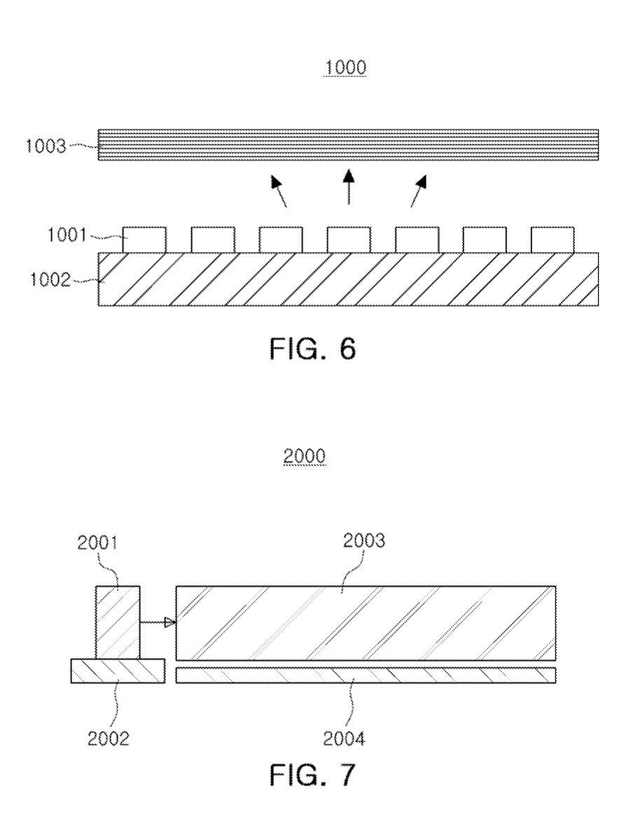

FIGS. 6 and 7 are views illustrating examples of a backlight unit including a nanostructure semiconductor light emitting device according to an exemplary embodiment of the present disclosure.

Referring to FIG. 6, a backlight unit 1000 may include at least one light source 1001 mounted on a board 1002, and at least one optical sheet 1003 disposed above the light source 1001. The light source 1001 may be the aforementioned nanostructure semiconductor light emitting device or a package including the same.

The light source 1001 in the backlight unit 1000 of FIG. 6 emits light toward a liquid crystal display (LCD) disposed thereabove, whereas a light source 2001 mounted on a board 2002 in a backlight unit 2000 according to another embodiment illustrated in FIG. 7 emits light laterally and the light is incident to a light guide plate 2003 such that the backlight unit 2000 may serve as a surface light source. The light travelling to the light guide plate 2003 may be emitted upwardly and a reflective layer 2004 may be disposed below a lower surface of the light guide plate 2003 in order to improve light extraction efficiency.

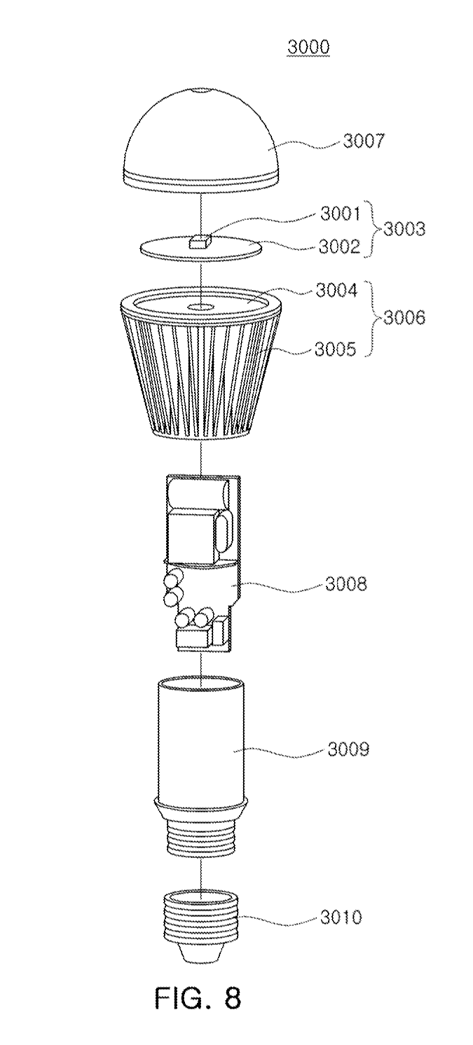

FIG. 8 is an exploded perspective view illustrating an example of a lighting device including a nanostructure semiconductor light emitting device according to an exemplary embodiment of the present disclosure.

A lighting device 3000 illustrated in FIG. 8 is exemplified as a bulb-type lamp, and may include a light emitting module 3003, a driver 3008, and an external connector 3010.

Also, the lighting device 3000 may further include exterior structures such as an external housing 3006, an internal housing 3009, and a cover 3007. The light emitting module 3003 may include a light source 3001 having the aforementioned package structure or a structure similar thereto, and a circuit board 3002 on which the light source 3001 is mounted. For example, the first and the second electrodes of the above-described semiconductor light emitting device may be electrically connected to electrode patterns of the circuit board 3002. According to this exemplary embodiment, a single light source is mounted on the circuit board 3002 by way of example; however, a plurality of light sources may be mounted on the circuit board, if necessary.

The external housing 3006 may serve as a heat radiator, and may include a heat sink plate 3004 directly contacting the light emitting module 3003 to thereby improve heat dissipation and heat radiating fins 3005 surrounding a side surface of the lighting device 3000. The cover 3007 may be disposed above the lighting module 3003 and may have a convex lens shape. The driver 3008 may be disposed inside the internal housing 3009 and be connected to the external connector 3010 such as a socket structure to receive power from an external power source. Also, the driver 3008 may convert the received power into power appropriate for driving the light source 3001 of the lighting module 3003 and supply the converted power thereto. For example, the driver 3008 may be provided as an AC-DC converter, a rectifying circuit, or the like.

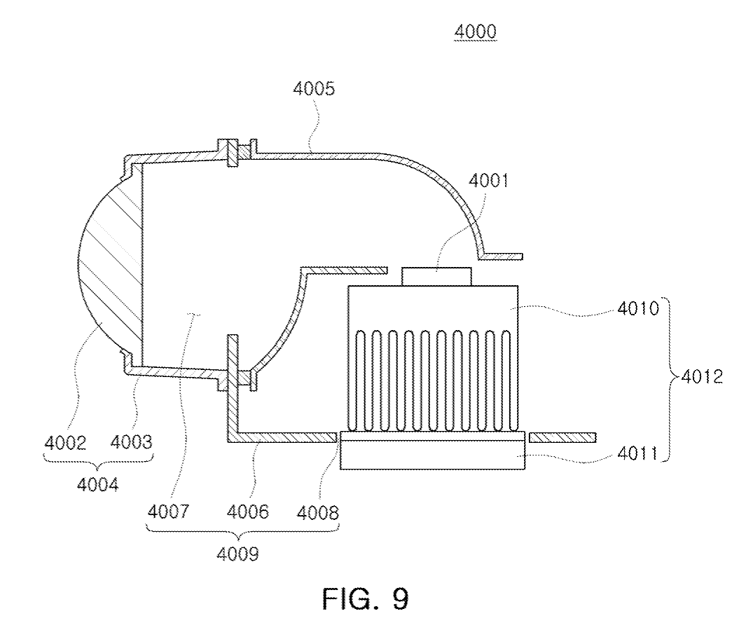

FIG. 9 is a view illustrating an example of a headlamp including a nanostructure semiconductor light emitting device according to an exemplary embodiment of the present disclosure.

Referring to FIG. 9, a headlamp 4000 used in a vehicle or the like may include a light source 4001, a reflector 4005 and a lens cover 4004, and the lens cover 4004 may include a hollow guide part 4003 and a lens 4002. The light source 4001 may include the aforementioned nanostructure semiconductor light emitting device or the aforementioned package having the same.

The headlamp 4000 may further include a heat radiator 4012 externally dissipating heat generated in the light source 4001. The heat radiator 4012 may include a heat sink 4010 and a cooling fan 4011 in order to effectively dissipate heat. In addition, the headlamp 4000 may further include a housing 4009 allowing the heat radiator 4012 and the reflector 4005 to be fixed thereto and supporting them. The housing 4009 may include a body 4006 and a central hole 4008 formed in one surface thereof, to which the heat radiator 4012 is coupled.

The housing 4009 may include a forwardly open hole 4007 formed in the other surface thereof integrally connected to one surface thereof and bent in a direction perpendicular thereto. The reflector 4005 may be fixed to the housing 4009, such that light generated in the light source 4001 may be reflected by the reflector 4005, pass through the forwardly open hole 4007, and be emitted outwards.

As set forth above, according to exemplary embodiments, a leakage current may be significantly reduced. In particular, by effectively blocking a path of the leakage current in a region disposed on tip portions of light emitting nanostructures, a high efficient nanostructure semiconductor light emitting device may be provided. In some exemplary embodiments, a leakage current generated between an insulating layer and a semiconductor layer may also be reduced. In addition, by only allowing portions of active layers grown on a single crystal plane to contribute to the emission of light, uniformity in emitted light may be achieved.

While exemplary embodiments have been shown and described above, it will be apparent to those skilled in the art that modifications and variations could be made without departing from the scope in the present invention as defined by the appended claims.

What is claimed is:

1. A nanostructure semiconductor light emitting device, comprising:
a base layer formed of a first conductivity-type semiconductor material;
an insulating layer disposed on the base layer and having a plurality of openings exposing portions of the base layer;
a plurality of nanocores disposed on the exposed portions of the base layer and formed of the first conductivity-type semiconductor material, each of which including a tip portion having a crystal plane different from that of a side surface thereof;
a first high resistance layer disposed on the tip portion of the nanocore and formed of an oxide containing an element which is the same as at least one of elements constituting the nanocore;
an active layer disposed on the first high resistance layer and the side surface of the nanocore; and
a second conductivity-type semiconductor layer disposed on the active layer.

2. The nanostructure semiconductor light emitting device of claim 1, further comprising a second high resistance layer disposed on a surface of the second conductivity-type semiconductor layer.

3. The nanostructure semiconductor light emitting device of claim 2, wherein the second high resistance layer is formed of an oxide containing an element which is the same as at least one of elements constituting the second conductivity-type semiconductor layer.

4. The nanostructure semiconductor light emitting device of claim 2, further comprising an ohmic-contact electrode disposed on the second conductivity-type semiconductor layer,
wherein at least a portion of the second conductivity-type semiconductor layer is exposed above the ohmic-contact electrode.

5. The nanostructure semiconductor light emitting device of claim 4, wherein the second high resistance layer is disposed on the exposed portion of the second conductivity-type semiconductor layer.

6. The nanostructure semiconductor light emitting device of claim 1, wherein the nanocores are provided in some of the plurality of openings, and
portions of the base layer exposed through the other openings are covered with a third high resistance layer.

7. The nanostructure semiconductor light emitting device of claim 6, wherein the third high resistance layer is formed of an oxide containing an element which is the same as at least one of elements constituting the first conductivity-type semiconductor material.

8. The nanostructure semiconductor light emitting device of claim 6, further comprising a second electrode covering the third high resistance layer.

9. The nanostructure semiconductor light emitting device of claim 1, wherein the first high resistance layer includes a material having a higher energy bandgap than that of the first conductivity-type semiconductor material forming the nanocore.

10. The nanostructure semiconductor light emitting device of claim 1, wherein the first high resistance layer is formed of Ga₂O₃ or Ga₃O₃N.

11. The nanostructure semiconductor light emitting device of claim 1, wherein the first high resistance layer has a thickness of approximately 100 nm or more.

12. The nanostructure semiconductor light emitting device of claim 1, wherein the side surface of the nanocore has an m-plane, and
the tip portion of the nanocore has an r-plane.

13. The nanostructure semiconductor light emitting device of claim 1, wherein the side surface of the nanocore has a crystal plane perpendicular to a top surface of the base layer.

14. A nanostructure semiconductor light emitting device, comprising:
a base layer formed of a first conductivity-type semiconductor material;
a plurality of light emitting nanostructures disposed on the base layer to be spaced apart from each other, each of which including a nanocore formed of the first conductivity-type semiconductor material and an active layer and a second conductivity-type semiconductor layer sequentially disposed on the nanocore; and
a high resistance layer disposed on a tip portion of the nanocore and formed of an oxide containing an element which is the same as at least one of elements constituting the second conductivity-type semiconductor layer.

15. The nanostructure semiconductor light emitting device of claim 14, further comprising an ohmic-contact electrode disposed on the plurality of light emitting nanostructures.

16. A nanostructure semiconductor light emitting device, comprising:
a base layer formed of a first conductivity-type semiconductor material;
an insulating layer disposed on the base layer and having a plurality of openings exposing portions of the base layer;
a plurality of light emitting nanostructures formed on the base layer, each light emitting nanostructure including a nanocore formed of the first conductivity-type semiconductor material and an active layer and a second conductivity-type semiconductor layer sequentially disposed on the nanocore; and
a plurality of oxide layers containing an element which is the same as at least one of elements constituting one of the nanocore and the second conductivity-type semiconductor layer,
wherein each opening overlaps with at least one of the oxide layers.

17. The nanostructure semiconductor light emitting device of claim 16, wherein a tip portion of one of the plurality of light emitting nanostructures includes one of the plurality of oxide layers.

18. The nanostructure semiconductor light emitting device of claim 17, wherein the one of the plurality of oxide layers is interposed between the nanocore and the active layer.

19. The nanostructure semiconductor light emitting device of claim 17, wherein the one of the plurality of oxide layers is directly formed on the second conductivity-type semiconductor layer.

20. The nanostructure semiconductor light emitting device of claim 16, each nanocore includes a tip portion having a crystal plane different from that of a side surface thereof.
